(19) United States
(12) Patent Application Publication
(10) Pub. No.: US 2025/0246500 A1
(43) Pub. Date: Jul. 31, 2025

(54) SEMICONDUCTOR HEAT SPREADER BY TRANSFER APPLICATION

(71) Applicant: MELLANOX TECHNOLOGIES, LTD., Yokneam (IL)

(72) Inventors: Ran Hasson Ruso, Pardes Hanna-Karkur (IL); Dimitrios Kalavrouziotis, Papagou (GR); Ella Sanders, HaSolelim (IL); Paraskevas Bakopoulos, Ilion (GR); Elad Mentovich, Tel Aviv (IL)

(21) Appl. No.: 18/427,065

(22) Filed: Jan. 30, 2024

(30) Foreign Application Priority Data
Jan. 25, 2024 (GR) 20240100054

(51) Int. Cl. H01L 23/367; H01L 23/373

(52) U.S. Cl. CPC H01L 23/3672; H01L 23/3738

(57) ABSTRACT

Systems and methods herein are for semiconductor product to include landing areas, where the landing areas may include at least one hot area to occur during operation of the semiconductor product, where the semiconductor product may also include heat spreader material from a transfer application, and wherein the heat spreader material may be conformal in the landing areas and can spread heat associated with the at least one hot area to at least one dissipation area of the semiconductor product.

### CROSS-REFERENCE TO RELATED APPLICATION

This application claims the benefit of priority to Greek application No. 20240100054, filed on Jan. 25, 2024, entitled “SEMICONDUCTOR HEAT SPREADER BY TRANSFER APPLICATION,” the entire disclosure of which is incorporated by reference herein for all intents and purposes.

### TECHNICAL FIELD

At least one embodiment pertains to a semiconductor product having a heat spreader for optimally spreading heat to be dissipated from the semiconductor product for cooling purposes.

### BACKGROUND

Developments in semiconductor products, including in circuit boards and semiconductor chips, have contributed to increased heat generated from such semiconductor products. For example, silicon circuits of the semiconductor product perform compute, storage and other operations that may be intensive operations that contribute to increased heat generation. The heat can have an impact on utilization and performance of the semiconductor product. For example, the heat can adversely impact compute potential of current and next-generation semiconductor products, including of next-generation silicon-based processors. Transfer of heat to heatsinks or cold plates allow heat to be removed from a semiconductor product using air or liquid. To move heat to a heatsink or cold plate, different thermal interface materials (TIMs) may be used. This allows vertical heat transfer from a semiconductor product to the heatsink or cold plate. Further, this may also allow horizontal heat spreading that moves heat across a semiconductor product. In another example, spot cooling of a semiconductor product allows heat to be moved away using a transfer via liquid. However, as heat generated by a semiconductor product may not be uniform and may change according to components in operation, the use of TIMs alone may not optimize cooling in scenarios where the heat generated is not homogeneous across the chip. For example, cooling may not be optimized if full contact with areas requiring cooling is not provided.

### BRIEF DESCRIPTION OF DRAWINGS

FIG. 1 is an illustrative plan view of a semiconductor product subject to a heat spreader by a transfer application, in at least one embodiment;

FIG. 2 is an illustration of a transfer application of a heat spreader material to a semiconductor product, in at least one embodiment;

FIG. 3 illustrates aspects of mapping of hot areas and dissipation areas of a semiconductor product for a transfer application of the heat spreader material, in at least one embodiment;

FIG. 4 illustrates computer and processor aspects of a transfer application system that supports application of a heat spreader by a transfer application to a semiconductor product, according to at least one embodiment;

FIG. 5 illustrates a process flow for a heat spreader by a transfer application on a semiconductor product, according to at least one embodiment;

FIG. 6 illustrates yet another process flow for a heat spreader by a transfer application and using a map of hot areas and dissipation areas of a semiconductor product, according to at least one embodiment; and

FIG. 7 illustrates a further process flow for operating a semiconductor productor having a heat spreader by a transfer application, according to at least one embodiment.

### DETAILED DESCRIPTION

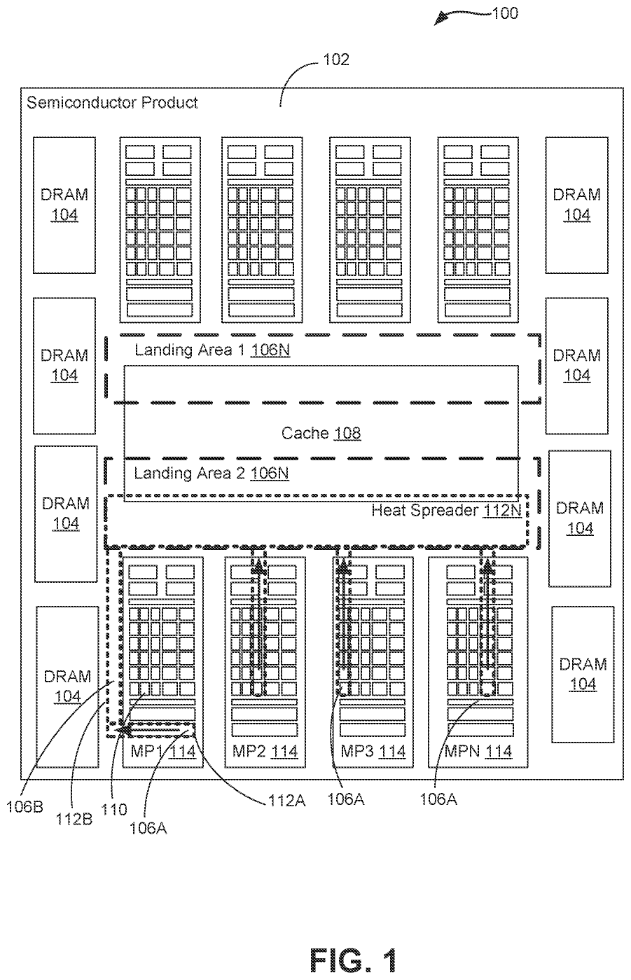

FIG. 1 is an illustrative plan view of a semiconductor product 100 subject to a heat spreader by a transfer application, in at least one embodiment. The heat spreader 112A-112N may be provided by a suitable material, such as graphene-based material. The heat spreader 112A-112N may be provided on a surface 102 of a semiconductor product 100. While illustrated as an integrated circuit, such as a graphics processing unit (GPU), a central processing unit (CPU), a data processing unit (DPU), or any other processing unit. In at least one embodiment, the semiconductor product 100 may be a circuit board, such as a printed circuit board (PCB). Further, as to at least the processing units, a form factor of the semiconductor product 100 that is a GPU, a CPU, or a DPU, may be a wafer form factor, a die form factor, or a packaged chip form factor.

Further, in FIG. 1, the semiconductor product 100 may include landing areas 106A-106N. At least two of the landing areas 106N are marked by long broken lines, whereas there may be further landing areas marked by callouts, such as in reference numerals 106A and 106B. The landing areas 106A-106N may be defined, in part, by components therein. However, in at least one embodiment, the landing areas may be defined generally on the surface 102 of the semiconductor product 100. For example, as illustrated, a first landing area 106A is on or around one or more cores 110 of a multiprocessor (MP) 114. There may be multiple such multiprocessors (MP1-MPN) 114 distributed through a semiconductor product 100. Further, FIG. 1 illustrates that a semiconductor product 100 may include other components, including a cache 108, such as a unified L2 cache, multiple dynamic random access memory (DRAM) 104, one or more memory controllers, and L1 caches.

In at least one embodiment, a first landing area may be predetermined hot areas or areas capable of generating more heat than other areas of the surface 102. The hot areas may generate heat as a result of an underlying one of the components, such as the cores of the MP 114. There may be second landing areas 106B-106N on the surface 102 of the semiconductor product 100. These second landing areas 106B-106N may not be heat generating areas or hot areas. Instead, these second landing areas 106B-106N may be areas that have lesser or no heat generated, relative to the hot areas 106A.

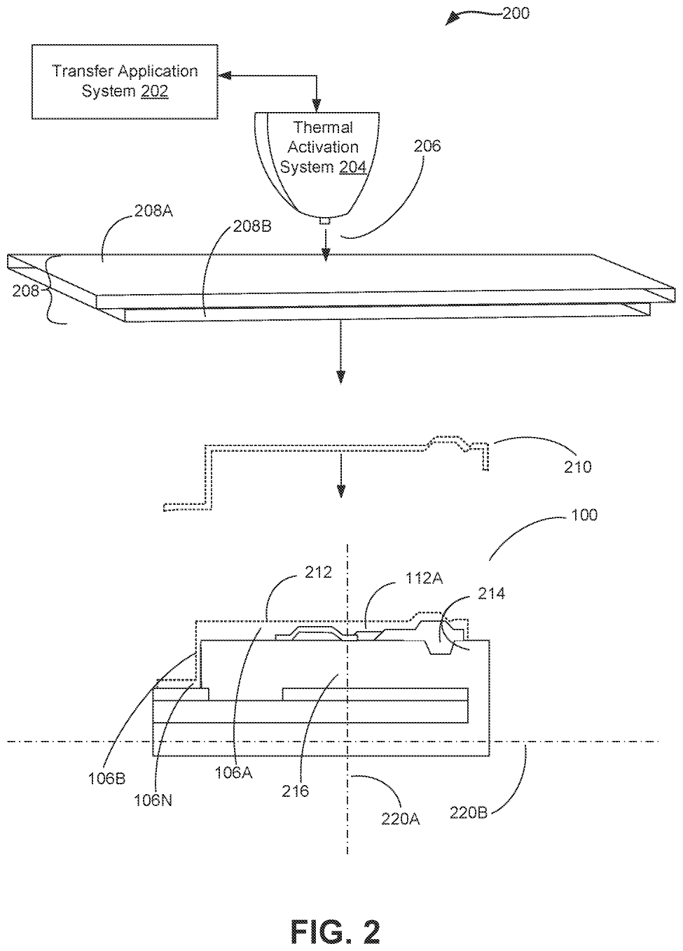

In at least one embodiment, the transfer application may be performed using a transfer substrate. The transfer substrate may be prepared with a heat spreader material thereon, as described further with respect to at least FIG. 2. In the transfer process, the heat spreader material may be provided in all or parts of the predetermined hot areas 106A, as well as other areas referenced as the second landing areas 106B-106N. Therefore, even though illustrated as confined in certain areas, the heat spreader material may be provided corresponding to all the landing areas or may be provided throughout the transfer substrate, as required to dissipate heat from certain hot areas to other areas of the surface 102 of the semiconductor product 100.

A laser may be used to activate a separation between the heat spreader material from the transfer substrate to cause the heat spreader material to be deposited conformally over the landing areas 106A-106N. In at least one embodiment, it is possible to deposit the heat spreader material to all or multiple landing areas at a time to create a first heat spreader 112A in a hot area 106A part of the landing areas, to create a heat spreader trace 112B in a trace area 106B part of the landing areas, which allows movement of heat from the hot area 106A, and to create a second heat spreader 112N which is in a dissipation area 106N part of the landing areas of the semiconductor product 100. Further, all or part of each landing area 106A-106N may be covered by the heat spreader 112A-112N. In at least one embodiment, each of the hot areas 106A and the dissipation areas 106N may be predetermined areas.

In addition, in at least one embodiment, it is possible to perform the transfer application for a heat spreader on a semiconductor product that is in a die format, a wafer format (which may be followed by cutting), or in a packaged semiconductor format of any type of package, including a stacked-die package and a multi-chip package (MCP). The transfer application herein is to provide heat spreader material, at about a one-micron scale, in any of these semiconductor products. Further, prior to transfer application, the heat spreader material may be referred herein by its material form, whereas, after the transfer application, the heat spreader material may be referred to herein as a function form, as a heat spreader or as a heat spreader comprising a heat spreader material.

The transfer application for the heat spreader material is able to provide a semiconductor product 100 that uniform heat generation relative to issues of non-uniform heat generation that may otherwise exist. For example, the non-uniform heat generation may be because of changes, according to components within the semiconductor product. A change, in one example, may be based in part on usage of such components in a computing environment. For example, memory usage may cause the memory components to generate more heat relative to other components on the surface of a semiconductor product, whereas processing usage may cause the processing components or cores to generate more heat relative to other components, including the memory components on the surface of a semiconductor product.

Heat removal from such semiconductor products may not, otherwise, be optimized or may not be based on a conformal heat spreader. For example, in scenarios in which the heat generated is not homogeneous across the semiconductor product, the heat removal is not optimized. The transfer application herein, however, ensures conformal heat spreader at micron levels for optimized heat removal. In a further example, some heat removal features may not be conformal and may not utilize a full contact area between the semiconductor product and a heatsink or cold plate. In such cases, any cooling ability may not be uniform across a surface area of the semiconductor product. However, the transfer application herein provides conformal heat spreader material in areas that generate heat, provides a heat spreader trace formed of the same heat spreader material to direct the heat from the areas that generate heat, and provides heat dissipation also formed from the same heat spreader material in areas to dissipate the heat. In at least one embodiment, the transfer application is able to provide all of such heat spreader material at the same time, as a conformal layer. As a result, the heat spreader material by a transfer application herein is able to address issues of improper contact between heating and cooling areas of a semiconductor product.

In at least one embodiment, a transfer application can deposit a heat spreader material at least at about a one-micron scale in a manner that is conformal to allow heat spreading from specific hot areas of the landing areas to dissipation areas of the landing areas, of the semiconductor product. The transfer application herein provides a high thermal transfer materials as the heat spreader material. For example, graphene or other two-dimensional (2D) materials (which may be substantially flat after application) capable of performing as a high thermal transfer material and capable of being applied by transfer application may be used. In at least one embodiment, as the transfer application can be applied to multiple landing areas at the same time, the transfer application may be seen as providing or creating patterns on a surface of a semiconductor product.

In at least one embodiment, the transfer application for the heat spreader material directs heat generated from at least one hot area of a semiconductor product, in a horizontal direction, away from the hot area. The hot area may be associated with complex compute circuits, such as Tensor® cores. The heat may be directed to relatively cooler areas on the surface of the semiconductor product. In doing so, there is also an enlargement of a contact area of the hot area, with respect to a heat removal system, such as heatsinks or cold plates. The heat removal system may be used with the transfer application of the heat spreader material. In at least one embodiment, as the heatsink or cold plate covers more than the hot area, the movement of heat allows the heat removal to occur from multiple areas for uniform heat removal. Altogether, the approaches herein allow for increased cooling of a semiconductor product 100. In FIG. 1, while at least part of the heat spreader 112N is illustrated as being within a landing area 106B, the heat spreader 112A-112N may be applied to fully or partly cover each of the landing areas 106A-106N. Further, for illustrative purposes, the heat spreader 112A-112N is provide with short broken lines all throughout herein. In addition, as illustrated, the transfer application is such that the heat spreader 112A-112N may be applied to simultaneously to cover hot areas 106A that generate the most heat, to cover transfer areas 106B that allow movement of heat using a heat trace 112B formed of the same heat spreader material, and to cover a heat dissipation part of the landing area 106N. As the heat spreader 112A-112N is formed all throughout using the same heat spreader material, these areas 106A-106N are interconnected. In at least one embodiment, therefore, this approach is to address issues from improper contact between hot areas and cold areas that may otherwise exist in a semiconductor product. Further, although referred to as a cold area, this is only in reference to an area generating no heat or less heat relative to a hot area or relative to an area comprising an underlying compute or storage circuit, for instance. Therefore, a cold area may have some heat from the neighboring hot areas, and may receive more heat by the heat spreader to make a heat distribution substantially uniform across the entire surface of a semiconductor product.

FIG. 2 is an illustration of a transfer application 200 of a heat spreader material to semiconductor product, in at least one embodiment. The transfer application 200 may include a transfer application system 202 to control the transfer application 200 of the heat spreader material 210 to the semiconductor product 100. In at least one embodiment, the semiconductor product 100 illustrated is in a die form factor or a wafer form factor, and is illustrated in a side view. The semiconductor product 100 may include one or more features 214 such as, interconnects, vias, and dielectric layers. The features 214 may include non-uniform surfaces on the semiconductor product 100. Further, the features 214 may overlay transistors or other structures 216 that belong to a compute circuit or a memory circuit of the semiconductor product 100. As such, these may be hot areas 106A, based in part on the usage of the semiconductor product 100.

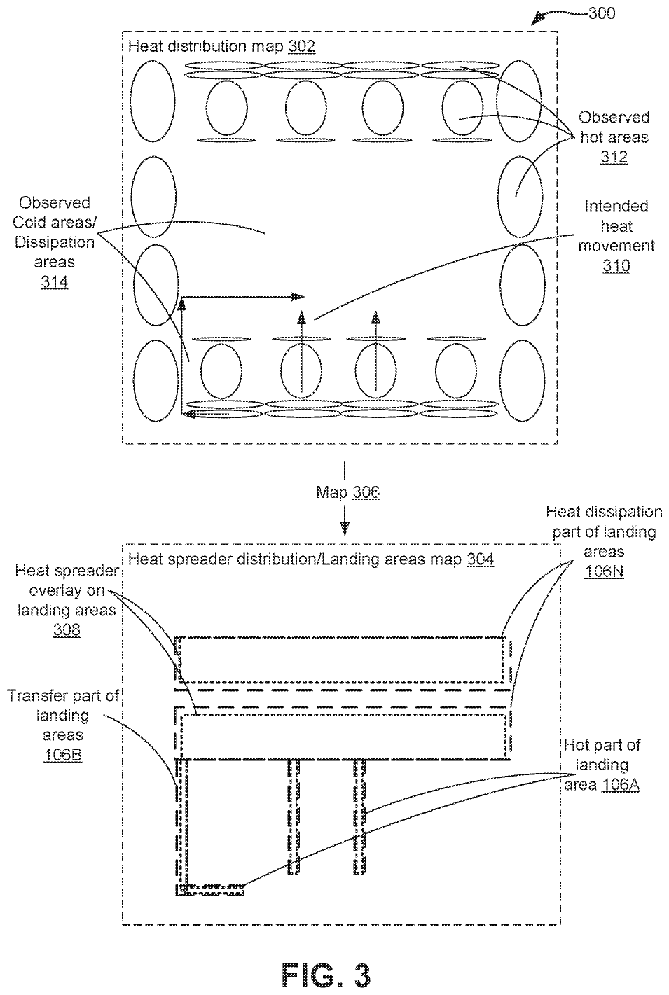

The transfer application system 202 is able to control a thermal activation system 204, such as a laser, to perform the transfer application 200. For example, the transfer application system 202 is able to activate a deposition of the heat spreader material. In one example, the heat spreader material 210 may be deposited based in part on a map of the hot areas and of the at least one dissipation area of the semiconductor product 100, as discussed further with respect to at least FIG. 3 herein. The map may include the heat transfer areas or parts of the landing area to place the heat spreader traces. The heat spreader material 210 once deposited in the semiconductor product 100 forms a heat spreader 212. For example, the heat spreader material 210 in a first one of the landing areas, reflecting a hot part 106A of the landing area, can receive heat from an underlying features 214 of the semiconductor product 100. The heat spreader material 210 in a second part of the landing areas, reflecting a transfer area 106B, can provide a heat spreader trace from the first part of the landing areas to the at least one dissipation part or area 106N of the landing area of the semiconductor product 100. The heat spreader material 210 in also illustrated as covering the at least one dissipation part 106N of the landing area of the semiconductor product 100.

In at least one embodiment, the transfer application 200 may be performed using a layered feature 208. The layered feature may be a flexible film that includes a transfer substrate 208A that may be prepared with a heat spreader material 208B thereon. In the transfer application 200, the heat spreader material 208B may be provided in all or parts of the hot areas 106A, as may be determined beforehand and as instructed by a laser using the transfer application system 202. For example, the thermal activation system 204 provides a thermal action 206 (such as a laser) that can cause thermal separation of the heat spreader material 210, as a conformal layer, from the heat spreader material 208B of the transfer substrate 208A. Once deposited on the surface of the semiconductor product 100, the separated heat spreader material 210 forms the heat spreader 212 to spread heat from the hot areas 106A, through a transfer part or area 106B, and to a dissipation part or area 106N of the landing areas on the semiconductor product 100.

As illustrated in FIG. 2, the thermal activation system 204 may be used to activate a separation between the heat spreader material 208B from the transfer substrate 208A to cause the separated heat spreader material 210 to be deposited as a single conformal layer over the landing areas 106A-106N. In at least one embodiment, it is possible to deposit the heat spreader material to all or multiple landing areas at a time to create a first heat spreader 112A in a hot area 106A part of the landing areas, a heat spreader trace 112B in a trace area 106B part of the landing areas, which allows movement of heat from the hot area 106A, and a second heat spreader 112N which is in a dissipation area 106N part of the landing areas of the semiconductor product 100. Further, all or part of each landing area 106A-106N may be covered by the heat spreader 112A-112N. In at least one embodiment, each of the hot areas 106A and the dissipation areas 106N may be predetermined areas fed into the transfer application system 202, which causes the thermal activation system 204 to activate the separation of the heat spreader material 208B over those areas of the semiconductor product 100.

In at least one embodiment, the at least one dissipation area 106N is part of the semiconductor product 100 but includes lesser heat generated relative to a neighboring part of the semiconductor product 100 that may include the features 214 that overlay transistors or other structures 216 belonging to a compute circuit or a memory circuit of the semiconductor product 100. Further, the heat spreader material 208B may be based in part on graphene. In at least one embodiment, a surface 102 of the semiconductor product 100 or the at least one dissipation area 106N may be associated with a heat removal system, such as a heat sink, a cold plate, or heat pipes. The heat removal system may be extending perpendicular 220A to a plane 220B of the semiconductor product. The heat removal system dissipates the heat in a vertical direction relative to the plane of the semiconductor product.

FIG. 3 illustrates aspects 300 of mapping of hot areas and dissipation areas of a semiconductor product for a transfer application of the heat spreader material, in at least one embodiment. In at least one embodiment, for any semiconductor product 100, a heat distribution map 302 between observed hot areas 312 and observed cold (or dissipation) areas 314 may be generated. The heat distribution map 302 may be generated using in-compute or in-application monitoring or observation of a sample of the semiconductor product 100 performing algorithms designed to stress the semiconductor product. In at least one embodiment, the heat distribution map 302 between observed hot areas 312 and observed cold (or dissipation) areas 314 may be generated using simulations of the semiconductor product prior to fabrication. Therefore, the algorithms may be applied to a system under test or to a simulation under test. The observed hot areas 312 may correspond to silicon parts of a semiconductor product, including of III-V semiconductors or compounds used in high-performance optoelectronic devices, heterogeneous, or micro-transfer printed (MTP) chips.

The heat distribution map 302 may be provided to a transfer application system 202 that supports a further map 306 between the heat distribution map 302 and a heat spreader distribution or landing areas map 304. For example, the heat spreader distribution or landing areas map 304 may include computer-generated linear (or other objective boundary feature) mark-outs of the observed hot areas 312 and the observed cold areas 314 from the heat distribution map 302. In one example, the intended heat movement 310 part of the heat distribution map 302 may be added based in part on a heat movement intended between the observed hot areas 312 and the observed cold areas 314.

Further, the heat spreader distribution or landing areas map 304 may include an applied heat spreader overlay 308 over landing areas 106A-106N marked therein. Although illustrated at different boundaries between the heat spreader overlay 308 and the landing areas 106A-106N, these boundaries may be identical so that the heat spreader material is applied to fully cover each landing area 106A-106N. In at least one embodiment, this process enables selective transfer application of transfer patterns of the heat spreader material 208D that may be a 2D material such as, graphene and capable of being laser-induced to optimizes heat spreading in a cost-efficient way. In at least one embodiment, the heat spreader material 208D may be Hexagonal boron nitride (h-BN). In at least one embodiment, the heat spreader material 208D may be black phosphorus that is subject to stability improvements in ambient conditions.

The landing areas for the heat spreader distribution or landing areas map 304 may be organized first for the intended hot areas 106A and the cold areas 106N. Thereafter, the movement 310 intended between the hot areas 106A and the cold area 106N may be determined. Then, the landing areas 106A-106N for the heat spreader may be designated or the heat spreader overlay 308 may be designated with or without the landing areas. This allows the heat spreader material to be applied to entire landing areas or to the specific areas marked by the heat spreader overlay.

In at least one embodiment, the heat spreader herein is able to offer uniformity, as a singular heat source in a heat distribution map 302 so that the hot areas and the cold areas illustrated do not exist. Otherwise, chip cooling may only be performed by taking the semiconductor product as a single uniform heat source, whereas in-plane heat spreading may not be achieved, as illustrated by the distinct the hot areas and the cold areas. The addition of a 2D heat spreader material as a layer with high thermal conductivity between the semiconductor product and a further, TIM as well as a further heat removal system, the heat distribution map 302 may be visualized as a uniform block of substantially same heat levels across an entire surface of the semiconductor product. Further, the pattern illustrated in the heat spreader distribution or landing areas map 304 is only an example, other design patterns may be used for one or more of the landing areas or the heat spreader overlay in the landing areas.

In at least one embodiment, the heat spreader material may be applied to the hot parts of the landing areas 106A and to the heat dissipating part of the landing areas 106N. Then, local bridging between the hot areas and heat dissipating part of the landing areas may be performed using transfer application for only the heat spreader traces in the transfer part of the landing areas 106B. Further, although referred to as a heat spreader trace, this trace is able to transfer heat from a hot area to a cold area or a dissipating part of the landing areas. The transfer of heat is a heat movement that is enabled in part by a temperature differential between the hot areas and the cold areas. This approach of transfer application for heat spreading may be particularly useful in optoelectronics semiconductor products, such an in an MTP or heterogeneously integrated devices. These semiconductor products may benefit from highly localized and contamination-free nature of the laser deposition transfer application process herein.

Further, as the number of computing units, per area of a semiconductor product increases, the number of hotspots on the semiconductor increases. Such semiconductor products may require faster and more efficient heat dissipation, which is provided by the transfer application herein. In addition, the heat generated in a semiconductor product may be due to electrical resistance of different components in the semiconductor product. The heat generated may be such that hotspots or hot areas are formed where the temperature is highest. While a heat removal system that includes heat sinks, liquid cooling, and air cooling may address part of a heat removal from the system, the transfer application of a heat spreader material herein is able to efficiently transfer the heat generated all throughout the semiconductor product. This is so that a destination of the heat generated, which is an important role in the overall efficiency of the heat removal process, is suitably under all contact surfaces of the heat removal system.

In one example, heat removal, from a semiconductor product may be supported via a TIM that is between a surface of the semiconductor product and the heat removal system to a heat sink. The TIM may be placed over an entire surface of the semiconductor product and may be intended to improve thermal contact between the semiconductor product and the heat removal system, which is to collect the heat in a vertical manner for substantially vertical dissipation. However, the thermal contact may be irregular and non-uniform. The approaches herein focus, in part, on transfer of heat generated from specific components and areas within the semiconductor product, whereas the use of the TIM and the heat removal system may be focused on a generalized cooling using the semiconductor product as a single uniform heat source with minimal in-plane heat spreading. There may be large difference in temperatures between the hot areas and the cold areas of the semiconductor product without the present transfer applied heat spreader material that may be used in addition to the TIM and the heat removal system.

For example, the addition of the transfer applied heat spreader material provides a layer with high thermal conductivity between the semiconductor product and the TIM, and provides a layer with a specific designed pattern for intended heat movement 310. This layer can improve thermal management, can improve in-plane heat spreading to larger surfaces of the semiconductor product. Further, the layer can transfer heat from the hot areas to the cold areas prior to the vertical dissipation using the heat removal system that may be a heatsink or a cold plate, for instance. The design of landing areas or the heat spreader overlay provides lateral thermal or heat spreader traces which are all fabricated in the 2D heat spreader material. Instead of the heat being transferred vertically in a direct manner from the semiconductor product, as it is generated in the different areas of the semiconductor product, the heat is first spread in-plane to reduce the temperature at the hot areas, prior to being removed.

In at least one embodiment, the transfer application of the heat spreader material herein also enables localized transfer of heat from hot areas to other areas of a semiconductor product. For example, a wafer or chip that is out of foundry may be subject to mapping of hot spots as described with respect to at least FIG. 3. The intent may be to spread out heat so that copper of a heat removal system that is vertically above the semiconductor product can take over to spread out the heat from the semiconductor product. As such and in one example, a wafer or film of graphene may be provided with a transfer substrate. Once the landing areas or the heat spreader overlay is determined, the transfer substrate may be aligned on top of semiconductor product and the laser activation may occur to transfer parts of the graphene to the semiconductor product to create patterns of the heat spreader thereon. This can occur at a one-micron scale and can be provided to cover micron scale components, including diodes.

Further, as the laser application is a clean and non-contaminated process, a level of purity in the heat spreader transfer application herein is unmatched. In one example, the transfer application herein may be applied for a GPU with optoelectronics and regular circuitry. An aspect of the transfer application herein may be able to use MTP for application of small pieces of laser or coupons on a semiconductor substrate, along with a subsequent heat spreader layer applied. In one example, photonic-crystal waveguide (PCW) may be used to provide slow light in optical modulators, switches, sensors, and for other optical signal processing. These features may be provided at a periphery of a semiconductor product, followed by metallization, and the heat spreader layer as a conformal layer over the irregular surface from such features on the semiconductor product. Further, a benefit realized is that there is no need to avoid electrodes as would otherwise be need in preventing shorting from other materials used for cooling.

In at least one embodiment, MTP herein may be also used for making transceiver engines and may reflect a superfine assembly and pickup process. For example, preparing a wafer during processing may need such superfine assembly for superfine coupons that can be simulated without cutting the wafer that may be a semiconductor product. After fabrication, a chemical-enabled release may be performed to transfer part of a wafer to a different substrate wafer. One or more of the transfer part of the wafer may be a laser or a modulator. A laser thermal application of the transfer part of the wafer may be accompanied by subsequent transfer application of the graphene.

In at least one embodiment, a wafer may have multiple die that may be included within predefined landing areas for the MTP. The MTP may be performed for the coupons on the wafer. There may be 2D arrays, 1D arrays, or other parallel process that is performed on the wafer. Subsequent to these processes, the wafer is ready to apply the graphene. A small wafer of graphene, relative to a size wafer forming the semiconductor product, is heated by laser to cause the thermal transfer application of the graphene to the landing areas or heat spreader overlay. Then, the wafer may be cut to provide individual packaged semiconductor product. For example, electrical and optoelectronics may be first transferred to a semiconductor wafer, then graphene, using laser transfer application, is added from above, as a subsequent but different step. These options indicate that a semiconductor product of any form factor can benefit from the present descriptions.

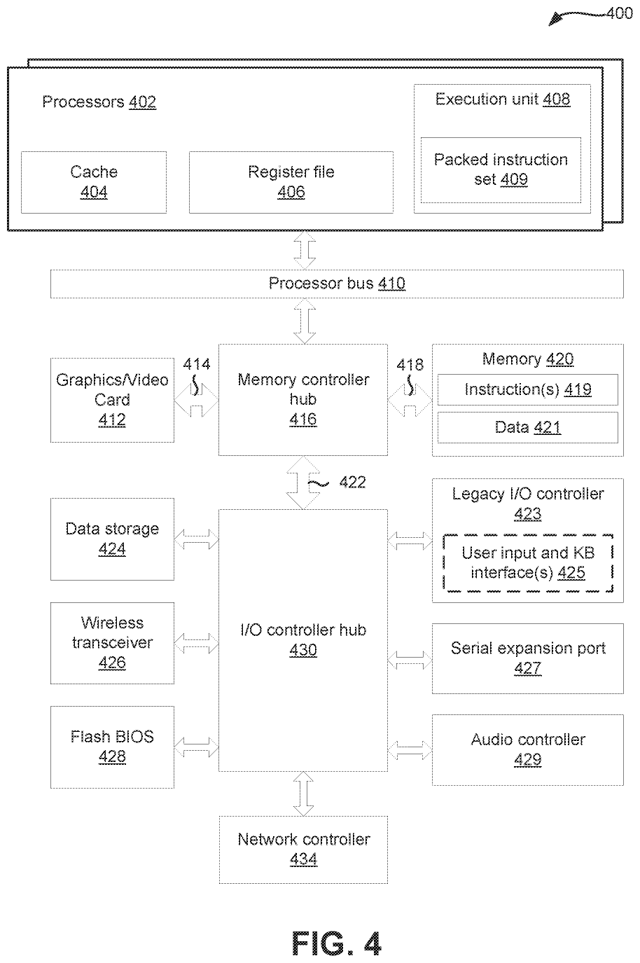

FIG. 4 illustrates computer and processor aspects 400 of a transfer application system that supports application of a heat spreader by a transfer application to a semiconductor product, according to at least one embodiment. For example, each of the illustrated processors 402 may include one or more processing or execution units 408 that can perform any or all of the features of the transfer application system. The transfer application system may include a human interface to receive one or more of the maps 302-306. However, the transfer application system herein can automatically monitor a sample semiconductor product, can automatically generate the heat spreader distribution or landing areas map, and can automatically cause the transfer application to be performed.

In at least one embodiment, the automation may be performed by one part of the computer and processor aspects 400 performing a stress algorithm for a sample semiconductor product. The automation may be further performed using another part of the computer and processor aspects 400 performing an observation or a monitoring for a semiconductor product performing the stress algorithm, to generate a heat distribution map for the semiconductor product. The automation is still further performed by a mapping part of the computer and processor aspects 400 that generates the heat spreader distribution or landing areas map, from the heat distribution map.

The processing or execution units 408 may include multiple circuits to support the automation described herein and the interface described herein. In at least one embodiment, the processors 402 may include CPUs, GPUs, DPUs that may be associated with a multi-tenant environment to perform one or more of the transfer application features described herein. Further, the GPUs may be distinctly in distinct graphics/video cards 412, relative to a DPU (represented by a network controller 434) and a CPU represented by the processors 402 illustrated in FIG. 4. Therefore, even though described in the singular, the graphics/video card 412 may include multiple cards and may include multiple GPUs on each card.

The computer and processor aspects 400 may be performed by one or more processors 402 that include a system-on-a-chip (SOC) or some combination thereof formed with a processor that may include execution units to execute an instruction, according to at least one embodiment. In at least one embodiment, the computer and processor aspects 400 may include, without limitation, a component, such as a processor 402 to employ execution units 408 including logic to perform algorithms for process data, in accordance with present disclosure, such as in embodiment described herein. In at least one embodiment, the computer and processor aspects 400 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, the computer and processor aspects 400 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, the computer and processor aspects 400 may include, without limitation, a processor 402 that may include, without limitation, one or more execution units 408 to perform aspects according to techniques described with respect to at least one or more of FIGS. 1-3 and 5-7 herein. In at least one embodiment, the computer and processor aspects 400 is a single processor desktop or server system, but in another embodiment, the computer and processor aspects 400 may be a multiprocessor system.

In at least one embodiment, the processor 402 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, a processor 402 may be coupled to a processor bus 410 that may transmit data signals between processors 402 and other components in computer and processor aspects 400.

In at least one embodiment, a processor 402 may include, without limitation, a Level 1 (“L1”) internal cache memory (“cache”) 404. In at least one embodiment, a processor 402 may have a single internal cache or multiple levels of internal cache. In at least one embodiment, cache memory may reside external to a processor 402. Other embodiments may also include a combination of both internal and external caches depending on particular implementation and needs. In at least one embodiment, a register file 406 may store different types of data in various registers including, without limitation, integer registers, floating point registers, status registers, and an instruction pointer register.

In at least one embodiment, an execution unit 408, including, without limitation, logic to perform integer and floating point operations, also resides in a processor 402. In at least one embodiment, a processor 402 may also include a microcode (“ucode”) read only memory (“ROM”) that stores microcode for certain macro instructions. In at least one embodiment, an execution unit 408 may include logic to handle a packed instruction set 409.

In at least one embodiment, by including a packed instruction set 409 in an instruction set of a general-purpose processor, along with associated circuitry to execute instructions, operations used by many multimedia applications may be performed using packed data in a processor 402. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, an execution unit 408 may also be used in microcontrollers, embedded processors, graphics devices, DSPs, and other types of logic circuits. In at least one embodiment, the computer and processor aspects 400 may include, without limitation, a memory 420. In at least one embodiment, a memory 420 may be a Dynamic Random Access Memory (“DRAM”) device, a Static Random Access Memory (“SRAM”) device, a flash memory device, or another memory device. In at least one embodiment, a memory 420 may store instruction(s) 419 and/or data 421 represented by data signals that may be executed by a processor 402.

In at least one embodiment, a system logic chip may be coupled to a processor bus 410 and a memory 420. In at least one embodiment, a system logic chip may include, without limitation, a memory controller hub (“MCH”) 416, and processors 402 may communicate with MCH 416 via processor bus 410. In at least one embodiment, an MCH 416 may provide a high bandwidth memory path 418 to a memory 420 for instruction and data storage and for storage of graphics commands, data, and textures. In at least one embodiment, an MCH 416 may direct data signals between a processor 402, a memory 420, and other components in the computer and processor aspects 400 and to bridge data signals between a processor bus 410, a memory 420, and a system I/O interface 422. In at least one embodiment, a system logic chip may provide a graphics port for coupling to a graphics controller. In at least one embodiment, an MCH 416 may be coupled to a memory 420 through a high bandwidth memory path 418 and a graphics/video card 412 may be coupled to an MCH 416 through an Accelerated Graphics Port (“AGP”) interconnect 414. In at least one embodiment, the graphics/video card 412 may be coupled to one or more of the processors 402 via a PCIe interconnect standard. Similarly, a network controller 424 may also be coupled to one or more of the processors 402 via a PCIe interconnect standard.

In at least one embodiment, the computer and processor aspects 400 may use a system I/O interface 422 as a proprietary hub interface bus to couple an MCH 416 to an I/O controller hub (“ICH”) 430. In at least one embodiment, an ICH 430 may provide direct connections to some I/O devices via a local I/O bus. In at least one embodiment, a local I/O bus may include, without limitation, a high-speed I/O bus for connecting peripherals to a memory 420, a chipset, and processors 402. Examples may include, without limitation, an audio controller 429, a firmware hub (“flash BIOS”) 428, a wireless transceiver 426, a data storage 424, a legacy I/O controller 423 containing user input and keyboard interface(s) 425, a serial expansion port 427, such as a Universal Serial Bus (“USB”) port, and a network controller 434. In at least one embodiment, data storage 424 may comprise a hard disk drive, a floppy disk drive, a CD-ROM device, a flash memory device, or other mass storage device.

In at least one embodiment, FIG. 4 illustrates computer and processor aspects 400, which includes interconnected hardware devices or “chips”, whereas in other embodiments, FIG. 4 may illustrate an exemplary SoC. In at least one embodiment, devices illustrated in FIG. 4 may be interconnected with proprietary interconnects, standardized interconnects (e.g., PCIe) or some combination thereof. In at least one embodiment, one or more components of the computer and processor aspects 400 that are interconnected using compute express link (CXL) interconnects.

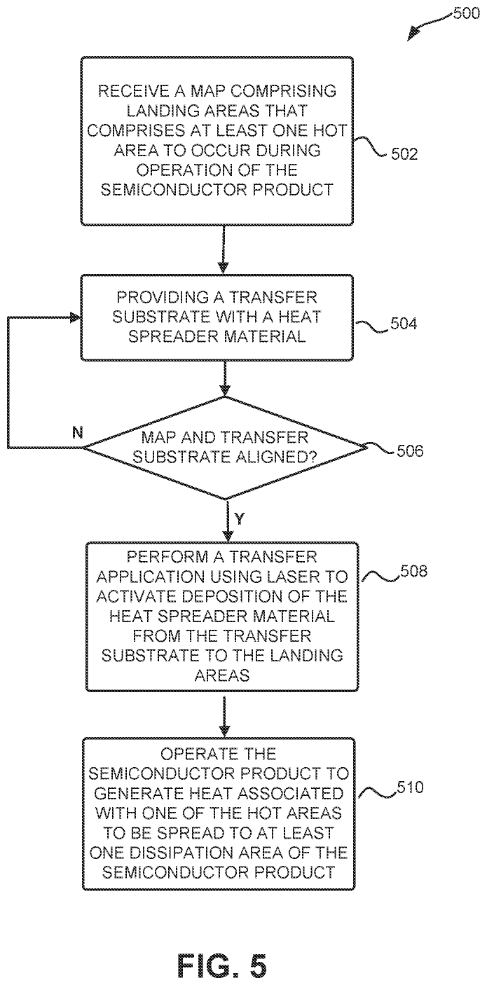

FIG. 5 illustrates a process flow or method 500 for a heat spreader by a transfer application on a semiconductor product, according to at least one embodiment. The method includes receiving 502 a map having landing areas for a semiconductor product. As detailed at least with respect to FIGS. 3 and 4, the map may be determined from a heat distribution map that is generated as part of an observation or a monitoring performed for a semiconductor product performing a stress algorithm. Therefore, the map of step 502 may include at least one hot area that is observed or monitored to occur during operation of the semiconductor product. For example, in at least one embodiment, the heat distribution map may be generated in physical testing at a post-fabrication stage or using simulations of the semiconductor product in a pre-fabrication stage. Further, the map of step 502 may be the heat spreader distribution or landing areas map of FIG. 3.

The method 500 includes providing 504 a transfer substrate with a heat spreader material thereon. As detailed with one or more of FIGS. 1-4, herein, the transfer substrate with the heat spreader material may be provided in the form factor or a film or a wafer to align with and overlay a semiconductor product that may also be a wafer or circuit components. In at least one embodiment, however, the transfer substrate with the heat spreader material may be applied to a die form factor, a packaged form factor, and a circuit board form factor.

The method 500 includes determining or verifying 506 that the map and transfer substrate are aligned. This may be performed by determining to provide the heat spreader material all throughout the landing areas or within less than the landing areas and only within a heat spreader overlay, for instance. The method 500 include performing 508 a transfer application using a thermal process to activate deposition of the heat spreader material from the transfer substrate to the landing areas based at least in part on the map. The heat spreader material is conformal in the landing areas to spread heat associated with one of the hot areas to at least one dissipation area of the semiconductor product during operation 510 of the semiconductor product.

In at least one embodiment, the method 500 may include a further step or sub-step of the thermal process including a laser-based transfer application to activate the deposition of the heat spreader material. The method 500 may include a further step or sub-step of the heat spreader material being deposited based in part on a map of the hot areas and the at least one dissipation area of the semiconductor product. Further, method 500 may include a further step or sub-step of the semiconductor product including wafers, dies, or packages, as form factors beneficial of the method 500 herein. In addition, at least part of the heat spreader material is applied, by the method 500, at about a one micron-scale in dimension.

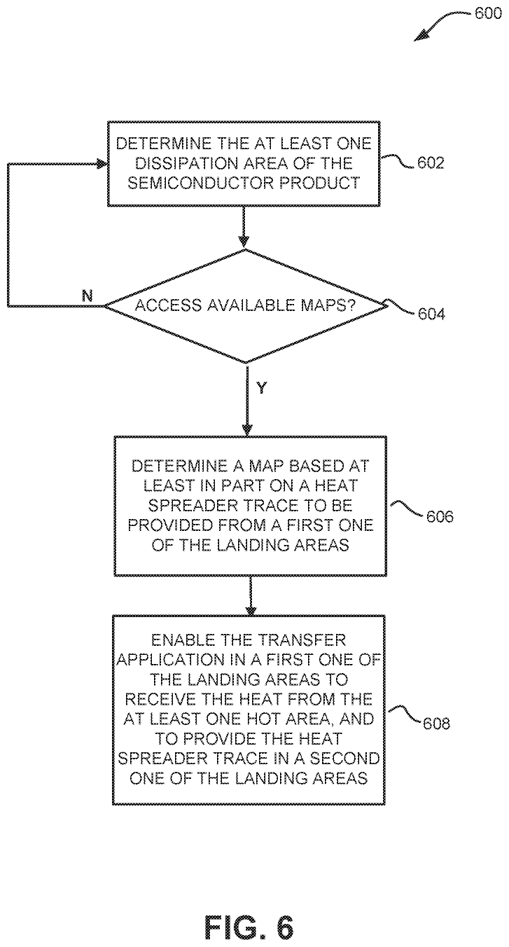

FIG. 6 illustrates yet another process flow or method 600 for a heat spreader by a transfer application and using a map of hot areas and dissipation areas of a semiconductor product, according to at least one embodiment. The method 600 of FIG. 6 may be used with the method 500 of FIG. 5. For example, the method 600 includes determining the at least one dissipation area of the semiconductor product, as part of an observing or monitoring performed prior to step 502 of the method 500 in FIG. 5.

The method 600 in FIG. 6 includes verifying or determining 604 that access is available to existing maps. For example, the semiconductor product may correspond to a map that may be accessed to provide the heat spreader distribution or landing areas for the semiconductor product. The heat spreader distribution or landing areas map may be automatically generated and stored for the semiconductor product and may be access by the method 600 in FIG. 6. The method 600 further includes determining 606 that the map is based at least in part on a heat spreader trace to be provided from a first one of the landing areas. For example, while the landing areas may be determined with respect to the hot and cold areas, a further heat spreader trace may be determined within the map to provide the specific areas for heat movement, as detailed with respect to at least FIG. 3 herein. Therefore, the landing areas of the map in step 606 may be associated with the at least one hot area and the at least one dissipation or cold area of the semiconductor product.

The method 600 includes enabling 608 the transfer application using the thermal process to provide at least one of the heat spreader material in a first one of the landing areas. The first one of the landing areas is to allow the heat spreader material to receive the heat from the at least one hot area. The method 600 includes enabling 608 the transfer application to provide the heat spreader trace in a second one of the landing areas as part of the enabling 608 step of the transfer application. The second one of the landing areas is a transfer area for the heat movement from the at least one hot area. Therefore, The method 600 includes enabling 608 the transfer application to provide the heat spreader trace to extend from the first one of the landing areas to the at least one dissipation area of the semiconductor product.

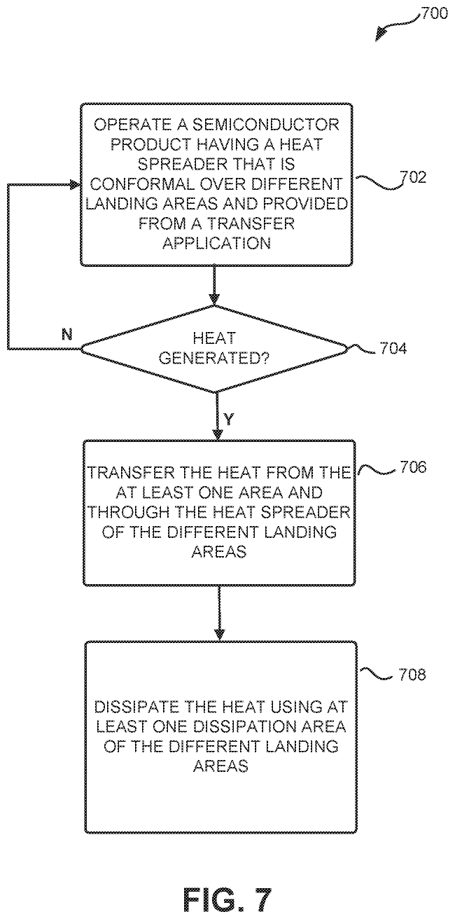

FIG. 7 illustrates a further process flow or method 700 for operating a semiconductor productor having a heat spreader by a transfer application, according to at least one embodiment. The method 700 of FIG. 7 may be used with the method 500 of FIG. 5 or the method 600 of FIG. 6. For example, the method 700 is for a semiconductor product having at least one hot area of different landing areas thereon, during operation of the semiconductor product, and having a heat spreader that is conformal over the landing areas and provided from a transfer application. The method 700 includes operating 702 the semiconductor product to generate heat from the at least one hot area of the different landing areas. This step 702 may correspond to the operating 510 step in FIG. 5.

The method 700 may include verifying 704 that heat is being generated. For example, the heat spreader material transfers heat in-plane once a temperature at a hot area is higher than a neighboring area to enable a differential temperature heat movement to occur. The method 700 includes transferring 706 the heat from the at least one hot area and through the heat spreader of a transfer area of the different landing areas. The method 700 includes dissipating 708 the heat using at least one dissipation area of the different landing areas. Therefore, one or more steps 702-708 of the method 700 in FIG. 7 may correspond to the operation 510 step of the semiconductor product, according to the method 500 of FIG. 5.

In at least one embodiment, the method 700 in FIG. 7 may include a further step or sub-step such that the transfer application includes a laser transfer application to activate deposition of a heat spreader material to form the heat spreader in the different landing areas. In at least one embodiment, the method 700 in FIG. 7 may include a further step or sub-step such that the heat spreader is deposited based in part on a map of the hot areas and the at least one dissipation area. In at least one embodiment, the method 700 in FIG. 7 may include a further step or sub-step such that the heat spreader material is in a first one of the different landing areas to receive the heat from an underlying feature of the semiconductor product. The underlying feature may be a circuitry for instance. The heat spreader is in a second one of the different landing areas and forms a heat spreader trace from the first one of the different landing areas to the at least one dissipation area of the semiconductor product.

In at least one embodiment, the method 700 in FIG. 7 may include the semiconductor product being wafers, dies, or packages. Further, in any of these form factors, at least one part of the heat spreader is at a one micron-scale in dimension. In at least one embodiment, the method 700 in FIG. 7 may include a further step or sub-step such that the at least one dissipation area is part of the semiconductor product and has lesser heat generated relative to a neighboring part of the semiconductor product. Further, a surface of the semiconductor product or the at least one dissipation area is associated with a heat removal system extending perpendicular to a plane of the semiconductor product to dissipate the heat in a vertical direction relative to the plane of the semiconductor product.

In the following description, numerous specific details are set forth to provide a more thorough understanding of at least one embodiment. However, it will be apparent to one skilled in the art that the inventive concepts may be practiced without one or more of these specific details.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A semiconductor product comprising landing areas including at least one hot area during operation of the semiconductor product, the semiconductor product further comprising heat spreader material from a transfer application, the heat spreader material being conformal in the landing areas to spread heat associated with the at least one hot area to at least one dissipation area of the semiconductor product.

2. The semiconductor product of claim 1, wherein transfer application comprises a laser transfer application to activate deposition of the heat spreader material to form a heat spreader in the landing areas.

3. The semiconductor product of claim 1, wherein the heat spreader material is deposited based in part on a map of the hot areas and the at least one dissipation area of the semiconductor product.

4. The semiconductor product of claim 1, further comprising the heat spreader material in a first one of the landing areas to receive the heat from the at least one hot area of the semiconductor product, and in a second one of the landing areas to provide a heat spreader trace from the first one of the landing areas to the at least one dissipation area of the semiconductor product.

5. The semiconductor product of claim 1, further comprising wafers, dies, or packages, wherein at least part of the heat spreader material is at a one micron-scale in dimension.

6. The semiconductor product of claim 1, wherein the at least one dissipation area is part of the semiconductor product and comprises lesser heat generated relative to a neighboring part of the semiconductor product.

7. The semiconductor product of claim 1, wherein the heat spreader material is based in part on graphene and wherein a surface of the semiconductor product or the at least one dissipation area is associated with a heat removal system extending perpendicular to a plane of the semiconductor product to dissipate the heat in a vertical direction relative to the plane of the semiconductor product.

8. A method for a heat spreader for a semiconductor product, the method comprising:
receiving a map comprising landing areas that comprises at least one hot area to occur during operation of the semiconductor product;
providing a transfer substrate with a heat spreader material; and
performing a transfer application using a thermal process to activate deposition of the heat spreader material from the transfer substrate to the landing areas based at least in part on the map, wherein the heat spreader material is conformal in the landing areas to spread heat associated with one of the hot areas to at least one dissipation area of the semiconductor product.

9. The method of claim 8, wherein the thermal process comprises a laser-based transfer application to activate the deposition of the heat spreader material.

10. The method of claim 8, wherein the heat spreader material is deposited based in part on a map of the hot areas and the at least one dissipation area of the semiconductor product.

11. The method of claim 8, further comprising:
determining the at least one dissipation area of the semiconductor product;
determining the map based at least in part on a heat spreader trace to be provided from a first one of the landing areas, which is associated with the at least one hot area, to the at least one dissipation area; and
enabling the transfer application to provide at least one of the heat spreader material in a first one of the landing areas to receive the heat from the at least one hot area, and to provide the heat spreader trace in a second one of the landing areas, the heat spreader trace to extend from the first one of the landing areas to the at least one dissipation area of the semiconductor product.

12. The method of claim 8, wherein the semiconductor product comprises wafers, dies, or packages, wherein at least part of the heat spreader material is at about a one micron-scale in dimension.

13. A transfer application system comprising a transfer substrate with a heat spreader material and comprising a laser to cause activation of the heat spreader material at landing areas of a semiconductor product, the landing areas comprising at least one hot area to occur during operation of the semiconductor product, the heat spreader material to be conformal in the landing areas and to spread heat associated with the at least one hot area to at least one dissipation area of the semiconductor product.

14. The transfer application system of claim 11, further comprising:
a controller module to control the laser based in part on a map of the landing areas and to enable the activation of the heat spreader material to provide at least one of the heat spreader material in a first one of the landing areas to receive heat from the at least one hot area, and to provide a heat spreader trace in a second one of the landing areas, the heat spreader trace to extend from the first one of the landing areas to the at least one dissipation area of the semiconductor product.

15. A method for a semiconductor product, the semiconductor product comprising at least one hot area of different landing areas thereon and comprising a heat spreader that is conformal over the landing areas and provided from a transfer application, the method comprising:
operating the semiconductor product to generate heat from the at least one hot area of the different landing areas;
transferring the heat from the at least one hot area and through the heat spreader of a transfer area of the different landing areas; and
dissipating the heat using at least one dissipation area of the different landing areas.

16. The method of claim 15, wherein transfer application comprises a laser transfer application to activate deposition of a heat spreader material to form the heat spreader in the different landing areas.

17. The method of claim 15, wherein the heat spreader is deposited based in part on a map of the hot areas and the at least one dissipation area.

18. The method of claim 15, wherein the heat spreader material is in a first one of the different landing areas to receive the heat from an underlying feature of the semiconductor product, and wherein the heat spreader is in a second one of the different landing areas and forming a heat spreader trace from the first one of the different landing areas to the at least one dissipation area of the semiconductor product.

19. The method of claim 15, wherein the semiconductor product further comprises wafers, dies, or packages, and wherein at least part of the heat spreader is at a one micron-scale in dimension.

20. The method of claim 15, wherein the at least one dissipation area is part of the semiconductor product and comprises lesser heat generated relative to a neighboring part of the semiconductor product, or wherein a surface of the semiconductor product or the at least one dissipation area is associated with a heat removal system extending perpendicular to a plane of the semiconductor product to dissipate the heat in a vertical direction relative to the plane of the semiconductor product.
